(19) United States
(12) Patent Application Publication
(10) Pub. No.: US 2025/0222555 A1
(43) Pub. Date: Jul. 10, 2025

(54) POLISHING CONTROL DEVICE, POLISHING CONTROL METHOD, AND SUBSTRATE POLISHING METHOD USING THE SAME

(71) Applicant: Samsung Electronics Co., Ltd., Suwon-si (KR)

(72) Inventors: Taekjin KIM, Suwon-si (KR); Meehyun LIM, Suwon-si (KR); Sung-Yeol KIM, Suwon-si (KR); Sunghwi CHO, Suwon-si (KR); Sung Yong PARK, Suwon-si (KR); Chansoo PARK, Suwon-si (KR); Jubyeong CHAE, Suwon-si (KR); Hoseop CHOI, Suwon-si (KR)

(73) Assignee: Samsung Electronics Co., Ltd., Suwon-si (KR)

(21) Appl. No.: 18/805,653

(22) Filed: Aug. 15, 2024

(30) Foreign Application Priority Data
Jan. 4, 2024 (KR) 10-2024-0001772

(51) Int. Cl. B24B 37/005; H01L 21/67

(52) U.S. Cl. CPC B24B 37/005; H01L 21/67253

(57) ABSTRACT

A polishing control device according to various example embodiments can be a polishing control device, comprising a head configured to mount a substrate, a platen facing the head with the substrate in between, a source in at least one of the head or the platen configured to generate a signal, a sensor configured to detect the signal transmitted through the substrate, the sensor being opposite the source and in at least one of the platen or the head and facing the source, and a controller configured to analyze the signal detected by the sensor and control the polishing of the substrate.

### CROSS-REFERENCE TO RELATED APPLICATION

This application claims priority to and the benefit of Korean Patent Application No. 10-2024-0001772 filed at the Korean Intellectual Property Office on Jan. 4, 2024, the entire contents of which are incorporated herein by reference.

### BACKGROUND

The present disclosure relates to a polishing control device, a polishing control method, and a substrate polishing method using the same.

The chemical mechanical polishing (CMP) process of semiconductors is a process of flattening the surface of a substrate using chemical reactions and mechanical (physical) forces.

The CMP process is a highly precise process that involves not only mechanical factors such as the rotation speed of the polishing pad and substrate, the pressure applied to the substrate, and the pattern directionality of the pad, but also chemical influences such as the interaction between the slurry polishing particles and the substrate surface, and the role of slurry organic additives, which act as important variables.

During the CMP process, a process called over-polishing is required to completely remove the metal layer due to non-uniformity in polishing within the substrate.

However, if dishing and corrosion of the pattern become severe due to over-polishing, it may have a significant impact on the reliability of the device. Therefore, an endpoint detection (EPD) device may be used to reduce (and/or minimize) over-polishing.

The EPD device is a device that monitors the polishing completion point in situ.

As representative EPD devices, there are known methods such as the monitor current method, the light-detection method, and the method using platen temperature, which utilize the physical and mechanical characteristics of the laminated layer at the point where the Ti film is almost polished and the interlayer insulating film is exposed during the CMP polishing process.

However, currently known EPD devices have limitations in that spatial resolution is not possible, measurement accuracy is low, and in particular, it is difficult to intensively measure the edge area of the substrate.

### SUMMARY

Various example embodiments of the present disclosure have been proposed to solve the above problems. By using a substrate transmission measurement method, sensitivity due to the angle at which each component is arranged can be lowered compared to the conventional reflective measurement method, and the signal generation part can provide a polishing control device, a polishing control method, and a substrate polishing method using the same that can increase the accuracy of the signal by shortening the distance from the sensor to detect the signal.

Also, by arranging a line-shaped source and multiple sensors, it aims to provide a polishing control device, a polishing control method, and a substrate polishing method using them, which can increase the accuracy of data by acquiring a large amount of data from the position to be measured.

Furthermore, various example embodiments of the inventive concepts aim to provide a polishing control device, a polishing control method, and a substrate polishing method for using them. Various example embodiments can precisely analyze the degree of polishing for specific areas of the substrate, especially the edge areas of the substrate, depending on the placement of the source and the sensor.

A polishing control device according to various example embodiments is a polishing control device, comprising a head configured to mount a substrate, a platen facing the head with the substrate in between, a source in at least one of the head or the platen configured to generate a signal, a sensor configured to detect the signal transmitted through the substrate, the sensor being opposite the source and in at least one of the platen or the head and facing the source, and a controller configured to analyze the signal detected by the sensor and control the polishing of the substrate.

A polishing control method according to various example embodiments is a polishing control method, comprising polishing a substrate between a head and a platen, rotating the head and the platen around their respective axes, generating a signal by a source in at least one of the head or the platen, detecting the signal passing through the substrate using a sensor, the sensor being opposite the source in at least one of the head or the platen and facing the source, analyzing, using a controller, the signal detected by the sensor, and controlling, using the controller, the polishing of the substrate based on the analyzing.

A substrate polishing method according to various example embodiments includes mounting a substrate on a head, rotating the head by a first drive shaft and rotating a platen by a second drive shaft, supplying a polishing liquid to a polishing pad on an upper surface of the platen and polishing the substrate on the polishing pad, generating a signal by a source in at least one of the head or the platen, detecting the signal transmitted through the substrate by a sensor facing the source, controlling the polishing of the substrate by analyzing a signal detected by the sensor using a controller, and determining the endpoint of the polishing process and ending the polishing process using the controller.

According to various example embodiments, by determining the degree of polishing of the substrate using a transmission measuring device, sensitivity due to structural factors is lowered compared to a conventional reflective measuring device. The accuracy of the signal and precision of measurement are improved, and the measured results are improved. By reflecting this, the substrate polishing can be controlled in real time according to the degree of substrate polishing.

### BRIEF DESCRIPTION OF THE DRAWINGS

FIG. 1 is a diagram illustrating a polishing control device according to various example embodiments.

FIG. 2 is a diagram illustrating a cross-section of the polishing control device according to FIG. 1.

FIG. 3 is a diagram illustrating a polishing control device according to various example embodiments.

FIG. 4 is a diagram illustrating a polishing control device according to various example embodiments.

FIG. 5 is a diagram illustrating the configuration of a polishing control device according to various example embodiments.

FIG. 6 is a diagram illustrating a polishing control method using a polishing control device according to various example embodiments.

FIG. 7 is a diagram illustrating a polishing control method using a polishing control device according to various example embodiments.

FIG. 8 is a diagram illustrating a polishing control method using a polishing control device according to various example embodiments.

### DETAILED DESCRIPTION

Hereinafter, with reference to the attached drawings, various example embodiments of the present disclosure will be described in detail so that those skilled in the art can easily practice them.

The present disclosure may be implemented in many different forms and is not limited to the example embodiments described herein.

In order to clearly explain the present disclosure in the drawings, parts not related to the description are omitted, and identical or similar components are given the same reference numerals throughout the specification.

In addition, since the size and thickness of each component shown in the drawings are arbitrarily shown for convenience of explanation, the present disclosure is not necessarily limited to that which is shown.

In the drawings, the thickness is enlarged to clearly express various layers and areas.

And in the drawings, for convenience of explanation, the thicknesses of some layers and regions are exaggerated.

Throughout the specification, when a part is said to be “connected” to another part, this includes not only cases where it is “directly connected” but also “indirectly connected” through another member.

Additionally, when a part “includes” a certain component, this means that it may further include other components, rather than excluding other components, unless specifically stated to the contrary.

Additionally, when a part of a layer, membrane, region, or plate is said to be “above” or “on” another part, this includes not only cases where it is “directly above” another part, but also cases where there is another part in between.

In contrast, when an element is referred to as being “directly on” another element, there are no intervening elements present.

In addition, being “above” or “on” a reference part means being located above or below the reference part, and does not necessarily mean being located “above” or “on” it in the direction opposite to gravity.

In addition, throughout the specification, when reference is made to “on a plane,” this means when the target part is viewed from above, and when reference is made to “in cross-section,” this means when a cross-section of the target part is cut vertically and viewed from the side.

Among the EPD technologies currently in use, the motor current (MC) method is the most widely used EPD technology. It uses the motor current of the rotating body, which represents the friction force generated during polishing, to detect changes in the polishing target medium, and by measuring the point (for example, the point where the dielectric changes to metal), the endpoint of the polishing process can be determined.

The motor current (MC) method has a disadvantage in that it is difficult to determine the polishing state of each substrate area.

Due to the friction force that varies depending on the film quality of the substrate, it is impossible to measure and analyze the changing motor current, or to spatially decompose it because one current is obtained as a representative value for the entire area of the substrate.

Additionally, if the friction coefficient is similar or there are multiple film materials, it is difficult to determine the polishing condition.

The method using the eddy current sensor may be used when the material to be polished is metal.

This is a method of placing a circuit that generates a magnetic field on the lower platen, generating current by the magnetic field generated, and measuring the eddy current generated in the top layer metal of the board using a sensor.

As polishing progresses, the metal layer that is the material to be polished becomes thinner, and the amount of flux passing through increases. Accordingly, the point where the value measured by the sensor decreases can be judged as the endpoint of the process.

In the case of the EPD method using the eddy current, additional signal processing is required to determine the location of the sensor that detects the signal on the board, and this process has a disadvantage in that it lowers accuracy.

The method using the optic sensor is to input light with a spectrum of hundreds of nanometers (nm) through the lower platen and analyze the spectrum of the light reflected from the pattern among the incident light.

In this type of reflective measurement method, the location where the source and sensor are placed is limited, so there is a disadvantage in that the measurement accuracy for specific locations on the substrate, such as the edge area of the substrate, is low.

Additionally, it utilizes the principle of light reflection from the source, and scattering can occur during the reflection process. It is greatly affected by the surrounding structure (causing noise), inevitably lowering the resolution, and there is a problem of high-sensitivity signal-to-noise ratio (SNR).

In addition, the light generated from the source placed on the platen passes through the window placed on the polishing pad, and the passed light is reflected back. As the head and the platen rotate, the reflected wave can only intermittently pass through the sensor, so the data detected by the sensor is not continuous.

The coordinates on the substrate measured by the sensor also have a problem of low accuracy.

The polishing control device 10, the polishing control method, and the substrate polishing method using the same according to various example embodiments are intended to solve the problems of the conventional EPD technology.

Hereinafter, the polishing control device 10, the polishing control method, and the substrate polishing method using the same according to various example embodiments of various example embodiments will be described in more detail with reference to the drawings.

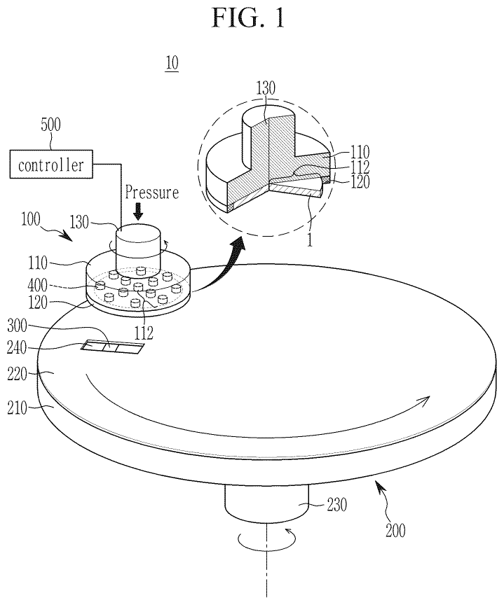

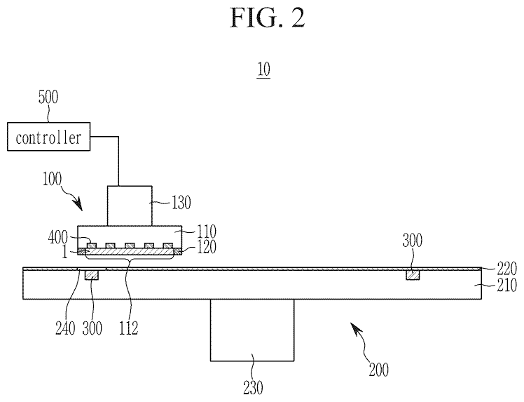

FIG. 1 is a diagram illustrating a polishing control device according to various example embodiments, and FIG. 2 is a diagram illustrating a cross-section of the polishing control device according to FIG. 1.

In FIG. 1 and referring to FIG. 2, the polishing control device 10 according to various example embodiments is a polishing control device 10 that controls polishing of the substrate 1 disposed between the head 100 and the platen 200.

As shown, the substrate 1 is mounted so as to contact the lower surface of the upper head 110, and the polishing pad 220 is located below the substrate 1.

The polishing control device 10 according to various example embodiments may include a head 100 for mounting a substrate 1, a platen 200 arranged to face the head 100 with the substrate 1 in between, a source 300 built into either the head 100 or the platen 200 to generate a signal, and a sensor 400 that can be built into the platen 200 or the head 100 to face the built-in source 300.

Here, the sensor 400 serves to detect a signal generated in the source 300 and transmitted through the substrate 1.

Additionally, the polishing control device 10 may include a controller 500 that controls polishing of the substrate 1 by analyzing the signal detected by the sensor 400.

The sensor 400 according to various example embodiments may be built into the platen 200 or the head 100, arranged to face the head 100 or the platen 200 in which the source 300 is built.

According to various example embodiments, if the source 300 is built into the head 100, the sensor 400 can be built into the platen 200, and if the source 300 is built into the platen 200, the sensor 400 can be built into the head 100.

For example, by the source 300 and the sensor 400 arranged to face each other with the substrate 1 in between, the signal generated and transmitted from the source 300 passes through the substrate 1 and reaches the sensor 400.

The head 100 according to various example embodiments includes an upper head 110 for mounting the substrate 1 on the lower part, a retaining ring 120 disposed on the lower surface of the upper head 110 to surround the circumference of the substrate 1. Connected to the upper part of the upper head 110 may include a first drive shaft 130 that rotates the upper head 110 about an axis perpendicular to the substrate 1.

The source 300 or the sensor 400 built into the upper head 110 may be disposed so that one surface is exposed on the contact surface 112 where the upper head 110 is in contact with the substrate 1.

Various example embodiments shown in FIGS. 1 and 2 are cases where the source 300 is built into the platen 200 and the sensor 400 is built into the upper head 110.

As described above, the source 300 and the sensor 400 may be arranged to face each other on the upper head 110 or the platen 200, and although not shown in the drawing, the source 300 may be built into the upper head 110, and the sensor 400 may be built into the platen 200.

In this case, only the location where the source 300 and the sensor 400 are placed are different, and the processes for controlling the generation of the signal, transmission of the signal, and polishing through signal analysis are the same.

The lower surface of the upper head 110 may be divided into a contact surface 112 in contact with the substrate 1 and a surface on which the retaining ring 120 is disposed.

As shown in FIGS. 1 and 2, the sensor 400 built into the upper head 110 of the head 100 can be arranged to include one side of the sensor 400 on the lower surface of the upper head 110.

For example, one surface of the sensor 400 may be disposed to be exposed toward the substrate 1 through the lower surface of the upper head 110.

At this time, the exposed surface of the sensor 400 is intended to be in contact with the substrate 1, and the sensor 400 may be disposed only on the contact surface 112 of the upper head 110.

The sensor 400 is not disposed in the area where the retaining ring 120 is disposed on the lower surface of the upper head 110.

According to the arrangement structure of the sensor 400 as described above, the polishing control device 10 according to various example embodiments allows a signal generated from the source 300 built in the platen 200 to detect the substrate 1. After penetration, it is directly transmitted to the sensor 400, which is disposed so that one side is in contact with the substrate 1.

Although not shown in the drawings, other various example embodiments may be when the source 300 is built into the upper head 110 and the sensor 400 is built into the platen 200, the source 300 may be arranged on the lower surface of the upper head 110 so that one surface of the source 300 is included.

For example, one surface of the source 300 may be disposed to be exposed toward the substrate 1 through the lower surface of the contact surface 112.

Among conventional EPD technologies, the motor current method had the disadvantage of not being able to accurately determine the degree of polishing on the substrate 1, which limited local control.

In addition, in the case of the EPD method using eddy current and optical interference, additional signal processing was required to determine the location of the sensor that detects the signal on the substrate 1, and this process had the disadvantage of lowering accuracy.

Additionally, only control of dispersion in the radical direction of the incoming substrate was possible, and asymmetry compensation was limited.

The polishing control device 10 according to various example embodiments improves the disadvantages of the prior art by including a source built into the upper head 110, and considering that the position of the upper head 110 is the position of the substrate 1, the position of the substrate 1 can be determined directly from the position of 300 or the sensor 400.

Accordingly, it is possible to map the degree of polishing and the position of the substrate 1, which has the advantage of being able to determine the distribution of the degree of polishing on the substrate 1 by region.

In addition, the polishing control device 10 according to various example embodiments is a transmission type in which the source 300 and the sensor 400, which transmit and receive signals, are arranged separately in the head 100 and the platen 200, respectively. In this regard, the sensitivity according to the posture (angle) of the substrate is small and the distance to sense the signal is shortened, which has the effect of increasing signal accuracy.

Additionally, because it is possible to compensate for the asymmetry of the incoming substrate, the endpoint of the polishing process can be determined more accurately compared to conventional EPD technology.

A signal generated by the source 300 according to various example embodiments may include at least one of light and electromagnetic waves.

Specifically, the signal in this disclosure may include an optical spectrum, current, magnetic field, etc., and can utilize light in the short wavelength range that can penetrate the substrate 1, or electromagnetic waves with a frequency sufficient to generate eddy currents.

The platen 200 according to various example embodiments is connected to the plate 210, the polishing pad 220 disposed on the upper surface of the plate 210, and the lower part of the plate 210, is positioned based on an axis perpendicular to the substrate 1, and it may include a second drive shaft 230 that rotates the plate 210.

The polishing pad 220 can transmit the signal generated by the source 300 to the sensor 400, as shown in FIGS. 1 and 2, the polishing pad 220 has a window 240 disposed thereon to allow light generated in the source 300 of the platen 200 to pass through and be directed toward the substrate 1.

FIG. 1 and FIG. 2 show only one window 240 disposed on the polishing pad 220, but one or more windows 240 through which optical signals pass may be disposed on the polishing pad 220.

In particular, in FIG. 1, it is shown that only a part of the source 300 is visible through the window 240 placed on the polishing pad 220, and the source 300 can be a structure placed further below the polishing pad 220 than what is shown in FIG. 1.

According to various example embodiments, the polishing pad 220 may have an electrically transparent property to allow electromagnetic wave signals to pass through, and can allow the electromagnetic waves generated from the source 300 of the platen 200 to pass through towards the substrate 1.

In this case, electromagnetic waves can pass through without including the window 240 described above.

Depending on various example embodiments, when the source 300 is built into the upper head 110 and the sensor 400 is built into the platen 200, the electromagnetic waves or light may pass through the polishing pad 220 and the substrate 1 and be directed to the sensor 400 disposed on the platen 200.

The source 300 or the sensor 400 built into the plate 210 may be placed on the upper surface of the plate 210 so that one surface is exposed.

Specifically, as shown in FIG. 2, the source 300 built into the plate 210 may be arranged so that the top surface of the source 300 is exposed to the top surface of the plate 210.

For example, the plate 210 may be disposed so that the upper surface of the source 300 is exposed on the upper surface that is in contact with the polishing pad 220.

According to various example embodiments, the source 300 is built into the upper head 110, and the sensor 400 is built into the platen 200, in this case, the sensor 400 built into the plate 210 of the platen 200 can be arranged so that the upper surface of the sensor 400 is exposed on the upper surface where the plate 210 comes into contact with the polishing pad 220.

One or more sources 300 according to various example embodiments may be disposed.

The source 300 may have a circular shape, and one or more circular-shaped sources 300 may be disposed on the head 100 or the platen 200.

When the circular-shaped source 300 is disposed on the platen 200, it is preferable that the source 300 be disposed on the platen 200 in an area where the head 100 passes.

Depending on various example embodiments, the source 300 may have a line shape.

When a plurality of sources 300 are built into the head 100 or the platen 200, they may have at least one of a circular shape and a line shape.

In some cases, the circular-shaped source 300 and the line-shaped source 300 may be built in at the same time.

As the number of sources 300 is arranged, the amount of signal transmitted to the sensor 400 increases, which means that the amount of data that can determine the degree of polishing increases.

The sensor 400 according to various example embodiments detects a signal generated in the source 300 and transmitted through the substrate 1, and a plurality of sensors 400 may be disposed.

Specifically, when the signal generated by the source 300 is an optical signal, the signal detected by the sensor 400 may include information such as the amount of spectrum, size, and spacing between valleys.

Additionally, if the signal generated from the source 300 is an electrical signal, it may include information such as frequency and signal strength.

As will be described below, in some cases, depending on the placement of the sensor 400, it may be possible to determine the degree of polishing in a specific area of the substrate 1 (for example, the edge).

In this case, depending on the location of the source 300, the location where the sensor 400 is placed is important.

The controller 500 according to various example embodiments analyzes the signal detected by the sensor 400 and controls polishing of the substrate 1.

In FIGS. 1 and 2, the controller 500 is shown connected to the head 100, according to various example embodiment.

According to various example embodiments, the controller 500 may be connected to the platen 200, and may be connected in an integrated manner or in a cable-connected structure.

Alternatively, the controller 500 may be structured to exchange signals with the sensor 400 using wireless communication.

The controller 500 analyzes the change in the signal detected by the sensor 400 to calculate at least one of the thickness of the polished substrate 1 and the thickness of the remaining film, and adjusts the pressure applied to the substrate 1 based on the calculated result.

In addition, the controller 500 can map the analyzed results to each area of the substrate 1, and can adjust the pressure applied to the head 100 through this.

According to the polishing control device 10 according to various example embodiments, if there is a deviation in each area of the substrate 1, it is possible to control the pressure for each area, and to control the polishing to match the uniformity through the area-specific pressure control, and it is also possible to determine the optimal endpoint of the polishing process.

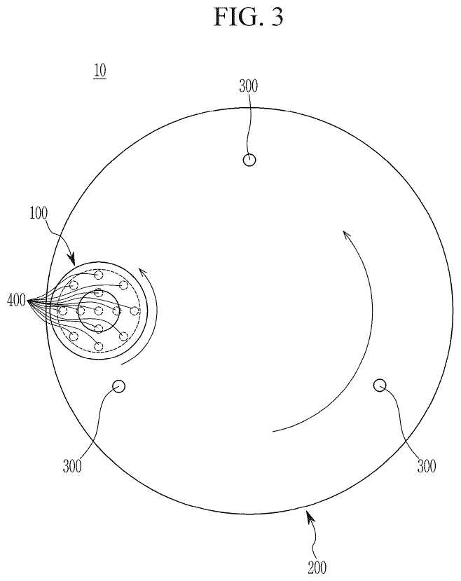

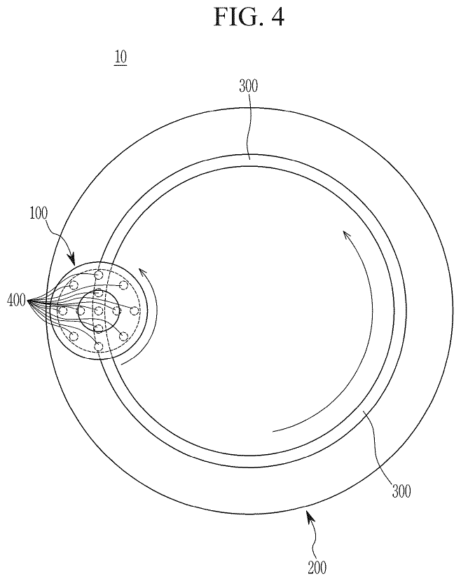

FIG. 3 is a diagram illustrating a polishing control device according to various example embodiments, and FIG. 4 is a diagram illustrating a polishing control device according to other example embodiments.

FIG. 3 and FIG. 4 are diagrams illustrating a top view of the polishing control device 10 according to various example embodiments. In order to explain the source 300 and the sensor 400, the sensor 400 built into the head 100 and the source 300 built into the platen 200 are shown.

As shown in FIGS. 3 and 4, the sensor 400 disposed on the head 100 may be disposed at the center of the substrate 1 mounted on the lower part of the head 100, and they can be additionally placed at regular intervals from the center of the substrate 1 in the vertical and horizontal directions.

The sensors 400 according to various example embodiments are arranged in plural numbers, and are not limited to the positions shown in FIGS. 3 and 4, and can be arranged in various positions such that one surface is placed on the contact surface 112 of the upper head 110.

FIGS. 3 and 4 show various example embodiments in which each source 300 disposed on the platen 200 has a different shape.

First, in various example embodiments as shown in FIG. 3, a plurality of sources 300 built into the platen 200 are arranged in the form of points, and in various example embodiments as shown in FIG. 4, the source 300 is arranged to have a single line shape (ring shape).

The source 300 according to various example embodiments may be arranged in a plurality of dot shapes, or may be arranged in one or more line shapes including a ring shape or a straight line shape.

The line-shaped source 300 is composed of a plurality of dot-shaped sources 300 arranged sequentially, and generates a continuous signal.

Referring to FIG. 4, the head 100 placed on the surface of the platen 200 can pass over the entire ring-shaped source 300 built into the platen 200 due to the rotation of the platen 200.

At the same time, because the head 100 also rotates, the plurality of sensors 400 built into the head 100 pass the ring-shaped source 300 at least once.

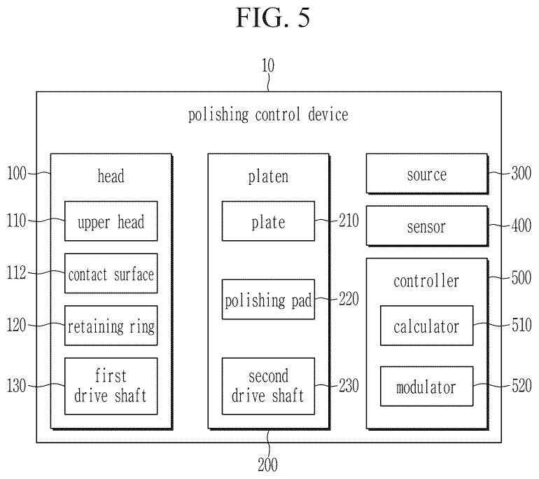

FIG. 5 is a diagram illustrating the configuration of a polishing control device according to various example embodiments.

As described above, the polishing control device 10 according to various example embodiments includes a head 100 and a platen 200, and includes the source 300 built into either the head 100 or the platen 200 generate a signal. And the polishing control device 10 includes a sensor 400, which is built into the platen 200 or head 100 to face the built-in source 300, detects the signal generated from the source 300 and transmitted through the substrate 1, and it may include a controller 500 that analyzes the signal detected by the sensor 400 and controls polishing of the substrate 1.

The controller 500 that controls polishing of the substrate 1 may include a calculator 510 and an modulator 520.

The calculator 510 analyzes the signal detected by the sensor 400 and calculates at least one of the polished thickness of the substrate 1 and the remaining film thickness, and the modulator 520, serves to control the pressure applied by the head 100 to the substrate 1.

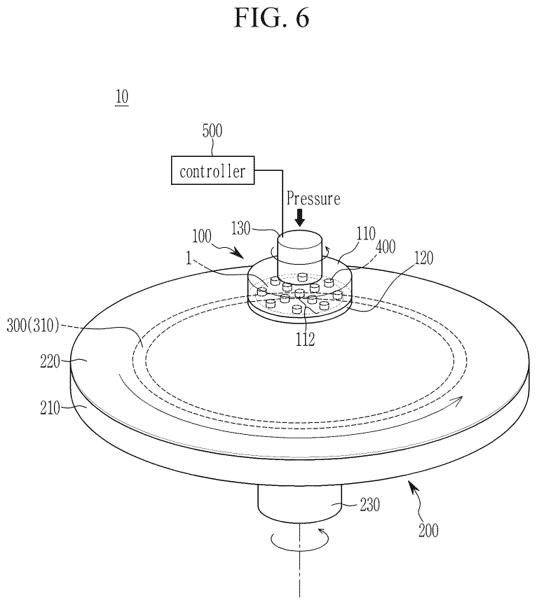

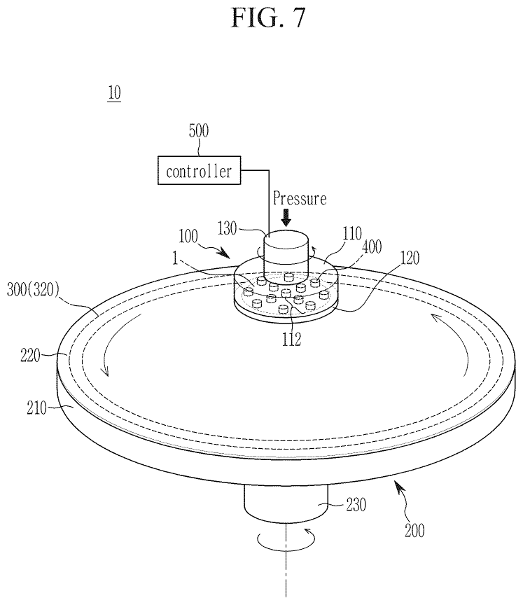

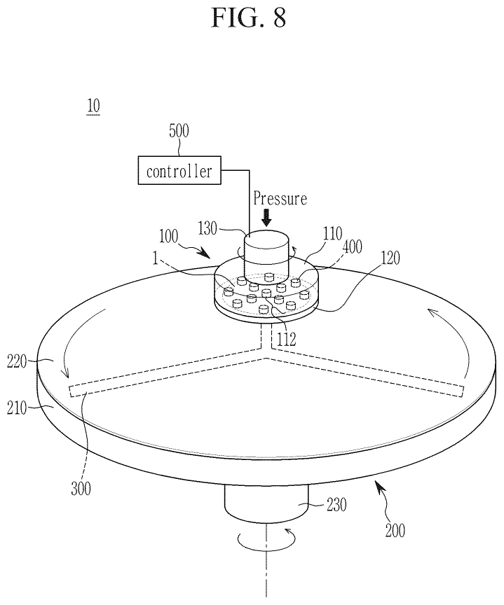

FIG. 6 is a diagram illustrating a polishing control method using a polishing control device according to various example embodiments, FIG. 7 is a diagram illustrating a polishing control method using a polishing control device according to other example embodiments, and FIG. 8 is a diagram illustrating a polishing control method using a polishing control device according to other example embodiments.

In FIG. 6 to FIG. 8, the substrate 1 is mounted below the upper head 110, the retaining ring 120 surrounds the mounted substrate 1, the sensor 400 is connected to the upper head 110, and it may be arranged so that one side is exposed to the contact surface 112 of the lower surface.

The head 100 in FIGS. 6 to 8 has the same structure as the head 100 in FIGS. 1 and 2.

Also, FIGS. 6 to 8 illustrate various example embodiments in which the sensor 400 is embedded in the head 100, and the source 300 is embedded in the platen 200, and the following description of FIGS. 6 to 8 is based on this assumption.

Depending on various example embodiments, the sensor 400 may be built into the platen 200, and the source 300 may be built into the head 100.

In this case, only the positions where the source 300 and the sensor 400 are placed are different, but the signal generation, transmission, analysis, and polishing control processes are the same.

The polishing control method using the polishing control device 10 according to various example embodiments is a method of controlling polishing of the substrate 1 disposed between the head 100 and the platen 200. First, it includes a step S100 in which the head 100 and the platen 200 rotate around their respective axes, and a step S200 in which the source 300 built into either the head 100 or the platen 200 generates a signal. Next, it includes a step S300 in which the sensor 400 built into the platen 200 or head 100, which is arranged to face the head 100 or platen 200 with a built-in the source 300, detect a signal transmitted through the substrate 1, and includes a step S400 in which the controller 500 analyzes the signal detected by the sensor 400 and controls polishing of the substrate 1.

Here, the rotation of the head 100 and the platen 200 may be such that the head 100 rotates by the first drive shaft 130, and the platen 200 rotates by the drive shaft 230, as shown in FIGS. 6 to 8.

While the head 100 rotates in place around the first drive shaft 130, the platen 200 rotates around the second drive shaft 230, and due to the rotation of the platen 200, the position where the head 100 is placed on the upper surface of the platen 200 changes with time.

Accordingly, relatively, the substrate 1 mounted on the head 100 can be seen as moving on the platen 200.

In the description below, it is assumed that the substrate 1 mounted on the head 100 moves on the platen 200, and the explanation is based on the moving path.

Firstly, according to various example embodiments of various example embodiments, as in FIG. 6, the source 300 built into the platen 200 may include a ring-shaped source 300 built along the path where the center of the substrate 1 mounted on the head 100 moves on the surface of the platen 200 due to the rotation of the platen 200.

In this way, the source 300 built along the movement path of the center of the substrate 1 is called the first source 310.

In FIG. 6, at each moment when the head 100 and the platen 200 are rotating, the center of the substrate 1 is disposed on the first source 310 disposed on the platen 200.

Additionally, due to the rotation of the upper head 110, the plurality of sensors 400 arranged on the contact surface 112 of the upper head 110 may pass over the first source 310 at least once.

As shown in FIG. 6, when the ring-shaped first source 310 built into the platen 200 is arranged along the path through which the center of the substrate 1 passes, the sensor 400 is connected to the upper head 110 (specifically, the contact surface 112), while the platen 200 makes one turn, all of the sensors 400 display at least one piece of polishing-related data.

In other words, during one rotation (turn) of the platen 200, the ring-shaped first source 310 placed on the platen 200 may pass over a specific location of the substrate 1 at least once.

Other example embodiments, as shown in FIG. 7, the source 300 built into the platen 200 causes the edge of the substrate 1 to move to the platen 200, and it may include a ring-shaped source 300 built along a moving path at the top.

In this way, the ring-shaped source 300 built along the movement path of the edge of the substrate 1 is called the second source 320.

The radius of the second source 320 may be larger or smaller than that of the first source 310.

As in FIG. 7, when the ring-shaped second source 320 built into the platen 200 is arranged to pass over the edge of the substrate 1, and multiple sensors 400 are arranged in the edge area of the upper head 110 (specifically, the contact surface 112), it is possible to continuously acquire data related to the polishing of the edge area of the substrate 1.

In the existing EPD technology, when using eddy current sensors and optic sensors, there is a limit to data acquisition because data must be obtained from a limited number of sensors installed on the lower platen. Even if focusing on measuring the edge area of the substrate 1 is desired, it is impossible to select the area. In other words, there is a problem with the conventional technology in that it is difficult to measure the film thickness in the edge area of the substrate 1, but when the source 300 and the sensor 400 are arranged as in FIG. 7, it becomes possible to continuously acquire the polishing-related data for the edge area of the substrate 1, which has the advantage of being able to accurately determine the degree of polishing in the edge area of the substrate 1.

In other words, in the case of a ring-shaped source 300 as in FIGS. 6 and 7, when rotation is carried out at the platen 200 and the head 100, it becomes possible to acquire polishing-related data more repetitively for a specific part of the substrate 1, thereby increasing the accuracy of the acquired data.

Other example embodiments, as shown in FIG. 8, the source 300 built into the platen 200 may not have a ring shape, but may have the shape of a plurality of straight lines passing through the center of the platen 200.

In the case of the linear-shaped source 300, as the platen 200 rotates, the entire surface of the substrate 1 can pass over the source 300, as in FIG. 8, when multiple linear-shaped sources 300 are arranged, the entire surface of the substrate 1 repeatedly passes over the source 300, making it possible to repeatedly acquire polishing-related data for the entire substrate 1.

Although not shown in the drawings, a straight-line shaped source 300 as in FIG. 8 and a ring-shaped source 300 as in FIG. 6 and FIG. 7 can all be arranged on a single platen 200.

Depending on various example embodiments, the platen 200 may include a planar source 300 so that it is embedded in the entire surface.

The more sources 300 are built in, the higher the accuracy of data can be.

In the polishing control process according to various example embodiments, the arrangement positions of the source 300 and the sensor 400 can be adjusted to specify and select a location in the area of the substrate 1 where the polishing degree is to be measured.

A specific area of the substrate 1 can be intensively measured, and the entire surface of the substrate 1 can also be measured.

Additionally, by adjusting the number or shape of the source 300 and the sensor 400, the accuracy of the data can be improved by increasing the amount of acquired data.

In the polishing control method according to this disclosure, the step S400 of controlling the polishing of the substrate 1 may include the step S410 in which the calculator 510 analyzes signals to calculate at least one of the thickness of the polished substrate 1 and the remaining film thickness, and the step S420 in which the modulator 520 adjusts the pressure applied by the head 100 to the substrate 1.

It may further include a step S412 in which the calculator 510 analyzes the signal detected by the sensor 400 to calculate the endpoint of the polishing process, and the modulator 520 performs the calculated polishing process, the polishing process can be adjusted to end at the endpoint.

Depending on various example embodiments, it may include a step S432 in which the modulator 520 adjusts the rotation speed of the head 100 and a step S434 in which the modulator 520 adjusts the rotation speed of the platen 200.

The polishing control according to various example embodiments uses a transmission method that directly detects the signal that has passed through the substrate 1, rather than reflecting the signal and detecting the reflected signal, so that the signal is immediately detected without separate signal processing, and the control process to control polishing can proceed quickly.

Since the location of the source 300 or the sensor 400 disposed on the head 100 is the location on the substrate 1, it may not be necessary for separate signal processing to find the location of the substrate 1 on the platen 200, enabling faster signal detection compared to the prior art.

In addition, by using a transmission method that immediately detects the signal that has passed through the substrate 1, the sensitivity to the tilt of the substrate 1 is not high and it is not greatly affected by noise.

The method of polishing a substrate 1 using a polishing control device 10 according to this disclosure includes the steps of mounting the substrate 1 under the head 100 (S90), rotating the head 100 by a first drive shaft 130, and rotating the platen 200 by a second drive shaft 230 (S100), supplying a polishing liquid to a polishing pad 220 placed on the surface of the platen 200, and polishing the substrate 1 on the polishing pad 220 (S110), a source 300 built into either the head 100 or the platen 200 generates a signal (S200), a sensor 400 built into the platen 200 or head 100 facing the source 300 detects a signal that has passed through the substrate 1 (S300), and a controller 500 analyzes the signal detected by the sensor 400 to control the polishing of the substrate 1 (S400), and the controller 500 can include a step of determining the endpoint of the polishing process and ending the polishing process (S500).

The step S400 of controlling the polishing of the substrate 1 may include a step S410 in which the calculator 510 analyzes the signal to calculate at least one of the thickness of the polished substrate 1 and the thickness of the remaining film.

Furthermore, the step S400 of controlling the polishing of the substrate 1 may include the step S420 where the modulator 520 adjusts the pressure applied by the head 100 to the substrate 1, and the modulator 520 may also include the step S430 of adjusting the rotation speed of the head 100 and the platen 200.

According to various example embodiments, the calculator 510 can analyze the signal to calculate the endpoint of the polishing process, and the modulator 520 can end the polishing process at the endpoint of the polishing process calculated by the calculator 510.

According to the polishing control device 10, the polishing control method and the substrate polishing method described above using the same, there is a difference compared to the existing EPD technology in that it can increase the accuracy of measurement in the process of measuring the degree of polishing of the substrate 1, and spatial decomposition is possible.

In particular, the measurement point can be adjusted depending on the number, shape, and location of the source 300 and the sensor 400 arranged on the head 100 and the platen 200, and the same area can be repeatedly measured, whereby the accuracy of the data acquired through measurement is increased, and compared to conventional EPD technology, the thin film information of the polished substrate 1 and the endpoint of the polishing process can be accurately determined.

Additionally, the source 300 and sensor 400 according to this disclosure are structures built into the platen 200 and head 100, and can use the polishing control device 10 without major structural changes such as volume changes of the CMP equipment itself.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a controller, a field programmable gate array (FPGA), a System-on-Chip (SoC), a programmable logic unit, a microprocessor, application-specific integrated circuit (ASIC), etc.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

While the above describes a preferred example embodiments of the present disclosure, it should be understood that it is possible to make various modifications within the scope of the patent claims, the detailed description, and the accompanying drawings, which also fall within the scope of the present disclosure.

What is claimed is:

1. A polishing control device, comprising:
a head configured to mount a substrate;
a platen facing the head with the substrate in between;
a source in at least one of the head or the platen configured to generate a signal;
a sensor configured to detect the signal transmitted through the substrate, the sensor being opposite the source and in at least one of the platen or the head and facing the source; and
a controller configured to analyze the signal detected by the sensor and control the polishing of the substrate.

2. The polishing control device of claim 1, wherein
the signal generated by the source includes at least one of light or electromagnetic waves.

3. The polishing control device of claim 1, wherein
the source has a circular shape, and one or more circular-shaped sources are on the head or the platen.

4. The polishing control device of claim 1, wherein
the source has a line shape including at least one of a straight line or a curved line.

5. The polishing control device of claim 1, wherein
the head comprises
an upper head configured to mount the substrate at a bottom thereof;
a retaining ring on the lower surface of the upper head to surround the circumference of the substrate; and
a first drive shaft connected to the upper part of the upper head, the drive shaft configured to rotate the upper head about an axis perpendicular to the substrate, and
the source or the sensor in the upper head, and the source or the sensor is configured such that one surface is exposed on a contact surface where the upper head is in contact with the substrate.

6. The polishing control device of claim 1, wherein
the platen comprises
a plate;
a polishing pad on the upper surface of the plate; and
a second drive shaft connected to a lower part of the plate and configured to rotate the plate about an axis perpendicular to the substrate.

7. The polishing control device of claim 6, wherein
the polishing pad is configured to transmit a signal generated by the source to the sensor.

8. The polishing control device of claim 6, wherein
the source or the sensor in the plate is on the upper surface of the plate such that one surface is exposed.

9. The polishing control device of claim 1, wherein
at least one of the platen or the head contains a plurality of sensors.

10. The polishing control device of claim 1, wherein
the controller comprises
a calculator configured to analyze the signal and calculate at least one of a polished thickness of the substrate or a remaining film thickness.

11. The polishing control device of claim 1, wherein
the controller comprises
a modulator configured to adjust the pressure applied by the head to the substrate.

12. The polishing control device of claim 1, wherein
the source includes a first source in the platen and has a ring shape.

13. The polishing control device of claim 12, wherein
the first source is on the upper surface of the platen such that the center of the substrate on the head is centered along the first source on the platen as the platen rotates.

14. The polishing control device of claim 1, wherein
the source includes multiple sources and at least one of the multiple sources is in the platen and has a ring shape, and
at least one of the multiple sources is on the upper surface of the platen, such that an edge of the substrate on the head is aligned with the at least one of the multiple sources on an upper surface of the platen.

15. A polishing control device, comprising:
a head configured to mount a substrate;
a platen facing the head with the substrate in between, comprising a plate and a polishing pad on the upper surface of the plate;
a source in at least one of the head or the platen configured to generate a signal;
a sensor configured to detect the signal transmitted through the substrate, the sensor being opposite the source and in at least one of the platen or the head and facing the source; and
a controller configured to analyze the signal detected by the sensor and control the polishing of the substrate, and
the polishing pad includes a window through which the signal passes.

16. The polishing control device of claim 15, wherein
the polishing pad contains one or more windows.

17. The polishing control device of claim 15, wherein
the controller comprises
a calculator configured to analyze the signal and calculate at least one of a polished thickness of the substrate or a remaining film thickness.

18. The polishing control device of claim 15, wherein
the controller comprises
a modulator configured to adjust the pressure applied by the head to the substrate.

19. The polishing control device of claim 18, wherein
the modulator adjusts the rotation speed of the head.

20. The polishing control device of claim 18, wherein
the modulator adjusts the rotation speed of the platen.
